(19) United States
(12) Patent Application Publication
(10) Pub. No.: US 2013/0031439 A1
(43) Pub. Date: Jan. 31, 2013

(54) SEMICONDUCTOR MEMORY APPARATUS AND SEMICONDUCTOR SYSTEM HAVING THE SAME

(71) Applicants: Young Suk MOON, Icheon-si (KR); Hyung Dong LEE, Icheon-si (KR); Yong Kee KWON, Icheon-si (KR); Hyung Gyun YANG, Icheon-si (KR); Sung Wook KIM, Icheon-si (KR)

(72) Inventors: Young Suk MOON, Icheon-si (KR); Hyung Dong LEE, Icheon-si (KR); Yong Kee KWON, Icheon-si (KR); Hyung Gyun YANG, Icheon-si (KR); Sung Wook KIM, Icheon-si (KR)

(73) Assignee: SK HYNIX INC., Icheon-si (KR)

(21) Appl. No.: 13/532,299

(22) Filed: Jun. 25, 2012

(30) Foreign Application Priority Data
Jul. 26, 2011 (KR) 10-2011-0074077

(51) Int. Cl. H03M 13/29; G06F 11/10; H03M 13/09

(52) U.S. Cl. 714/758; 714/805; 714/E11.032

(57) ABSTRACT

A semiconductor memory apparatus includes: a memory cell area including a plurality of memory cell arrays stacked therein, each memory cell array having a plurality of memory cells integrated and formed therein to store data and a plurality of through-lines formed therein to transmit signals; and a control logic area configured to generate parity bits using a data signal inputted to the memory cell area and transmit the generated parity bits and the data signal to different through-lines.

### CROSS-REFERENCES TO RELATED APPLICATION

The present application claims priority under 35 U.S.C. §119(a) to Korean application number 10-2011-0074077, filed on Jul. 26, 2011, in the Korean Intellectual Property Office, which is incorporated herein by reference in its entirety.

### BACKGROUND

1. Technical Field

The present invention relates to a semiconductor system, and more particularly, to a stacked semiconductor memory apparatus having an error correcting code (ECC) circuit and a semiconductor system having the same.

2. Related Art

In a conventional semiconductor system, a problem of reduction in reliability and yield has been raised with the increase in capacity. Accordingly, the conventional semiconductor system additionally includes an ECC circuit to correct or reduce an error of a failed memory cell, thereby solving the problem of reduction in reliability and yield.

Such an ECC circuit generates parity data from input data and corrects an error when the data are outputted. Typically, the ECC circuit is included in a memory controller of the general semiconductor system.

However, the memory controller of the conventional semiconductor system should participate in processing commands and address signals inputted from outside and transmitting data signals in addition to the operation of the ECC circuit. Therefore, the overhead of the memory controller may occur.

Furthermore, since the memory controller of the conventional semiconductor system processes a large number of operations as described above, the amount of power consumed by the memory controller increases further than other units.

Furthermore, an additional protocol agreement is required between the memory controller and a semiconductor memory apparatus in the conventional semiconductor system. Accordingly, the cost inevitably increases.

### SUMMARY

A semiconductor memory apparatus capable of reducing the overhead and power consumption of a memory controller and a semiconductor system having the same are described herein.

In one embodiment of the present invention, a semiconductor memory apparatus includes: a memory cell area including a plurality of memory cell arrays stacked therein, each memory cell array having a plurality of memory cells integrated and formed therein to store data and a plurality of through-lines formed therein to transmit signals; and a control logic area configured to generate parity bits using a data signal inputted to the memory cell area and transmit the generated parity bits and the data signal to different through-lines.

In another embodiment of the present invention, a semiconductor system includes: a memory controller configured to receive a command signal, an address signal, a data mask signal, and a data signal from outside and control data to be written or read; and a semiconductor memory apparatus configured to receive write data from the memory controller, generate parity bits using the write data, transmit the write data and the parity bits to different through-lines, determine whether read data outputted to the memory controller have an error or not, and transmit the read data.

### BRIEF DESCRIPTION OF THE DRAWINGS

Features, aspects, and embodiments are described in conjunction with the attached drawings, in which:

FIG. 1 is a block diagram illustrating the configuration of a semiconductor system according to one embodiment;

FIG. 2 is a block diagram illustrating the configuration of a semiconductor memory apparatus according to the embodiment;

FIG. 3 is a block diagram illustrating an ECC circuit of the semiconductor memory apparatus according to the embodiment;

FIG. 4 is a flow chart showing a control method during a data write operation of the semiconductor memory apparatus according to the embodiment; and

FIG. 5 is a flow chart showing a control method during a data read operation of the semiconductor memory apparatus according to the embodiment.

### DETAILED DESCRIPTION

Hereinafter, a semiconductor apparatus and a semiconductor system having the same according to the present invention will be described below with reference to the accompanying drawings through exemplary embodiments.

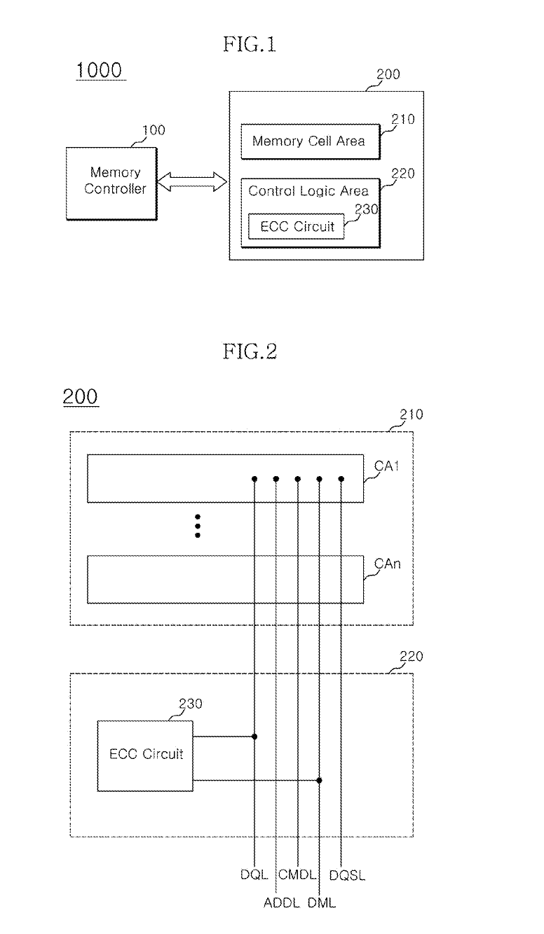

FIG. 1 is a block diagram illustrating the configuration of a semiconductor system according to one embodiment.

Referring to FIG. 1, the semiconductor system 1000 according to the embodiment may include a memory controller 100 and a semiconductor memory apparatus 200.

The memory controller 100 is configured to receive a command signal, an address signal, and a data signal from outside, i.e., from a host (not illustrated), and control data to be written into or read from the semiconductor memory apparatus 200.

The semiconductor memory apparatus 200 is configured to perform a data read or write operation according to a control signal outputted from the memory controller 100. The semiconductor memory apparatus 200 may include a memory cell area 210 in which cell arrays are integrated and a control logic area 220 configured to control the operation of the memory cell area 210. Here, the control logic area 220 may include an ECC circuit 230. Accordingly, when the data read from the memory cell area 210 have an error, the control logic area 220 corrects the error using the ECC circuit 230, and outputs the corrected data to the memory controller 100.

Furthermore, the memory cell area 210 of the semiconductor memory apparatus 200 according to the embodiment may have a structure in which a plurality of cell arrays each having a plurality of memory cells integrated therein are stacked in a vertical direction. In such a structure for implementing the high-capacity semiconductor memory apparatus 200, a plurality of through-lines (typically, referred to as through silicon vias (TSVs)) are formed through part or all of the plurality of cell arrays, and a data signal, a data mask signal, a command signal, an address signal, a strobe signal and the like are inputted from the memory controller 100 through corresponding through-lines.

The semiconductor memory apparatus 200 including the ECC circuit 230 in the semiconductor system 1000 according to the embodiment will be described in more detail.

FIG. 2 is a block diagram illustrating the configuration of the semiconductor memory apparatus according to the embodiment.

Referring to FIG. 2, the semiconductor memory apparatus 200 according to the embodiment includes the memory cell area 210 formed by stacking a plurality of memory cell arrays CA1 to CAn in a vertical direction, and the memory cell area 210 receives a data signal DQ, an address signal ADD, a command signal CMD, a data mask signal DM, and a data strobe signal DQS from the memory controller 100. Here, FIG. 2 illustrates a case in which the memory cell area 210 of the semiconductor memory apparatus 200 is formed by stacking the plurality of memory cell arrays. However, the present invention is not limited thereto, but may be applied to one cell array having a plurality of memory cells integrated therein.

Here, when a write data signal WD is inputted to the semiconductor memory apparatus 200 according to the embodiment, the write data signal WD is inputted to the ECC circuit 230 provided in an extra space of the control logic area 220, and the ECC circuit 230 generates a hamming code consisting of parity bits using the write data signal WD. The hamming code generated in such a manner is transmitted to a data line DQL for transmitting the write data signal WD and a data mask line DML for transmitting the data mask signal DM. As such, the semiconductor memory apparatus 200 according to the embodiment requires only a protocol agreement between the memory cell area 210 and the control logic area 220 inside the semiconductor memory apparatus 200 without a protocol agreement with the memory controller 100. In this case, a data signal having an error is transmitted to the data mask line. Therefore, the cost may be reduced.

Meanwhile, when a data read signal is inputted to the semiconductor memory apparatus 200 according to the embodiment, data are read from the memory cell area 210 having the plurality of cell arrays integrated therein, and the hamming code consisting of parity bits, generated during the write operation, is compared to bits of the read data RD, in order to detect whether an error occurred or not. Then, when an error is detected, the error of the read data RD is corrected, and the corrected read data RD are outputted to the outside.

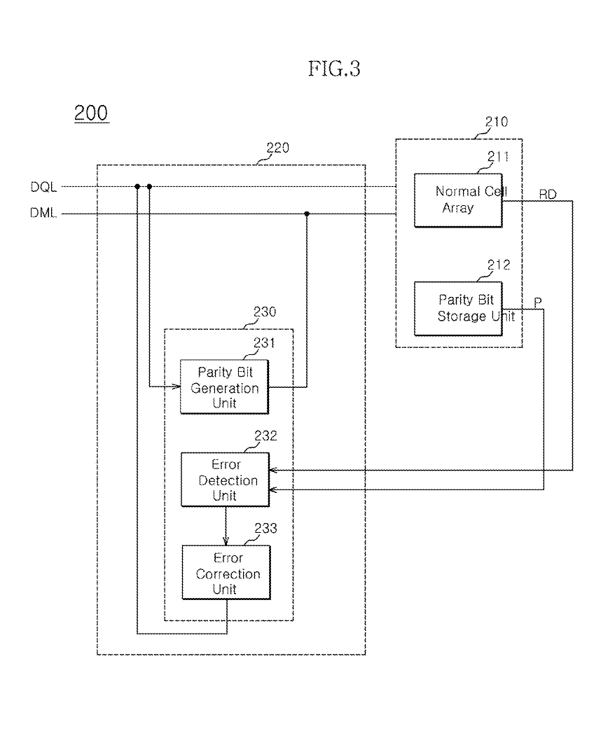

The ECC circuit 230 in the semiconductor memory apparatus 200 configured in such a manner will be described in more detail with reference to FIG. 3.

FIG. 3 is a block diagram illustrating the ECC circuit of the semiconductor memory apparatus according to the embodiment.

Referring to FIG. 3, the ECC circuit 230 of the semiconductor memory apparatus 200 according to the embodiment may include a parity bit generation unit 231, an error detection unit 232, and an error correction unit 233.

The parity bit generation unit 231 is configured to receive a write data signal WD from the memory controller 100 during a data write operation and generate a hamming code consisting of parity bits using the received write data signal WD. The hamming code generated in such a manner is transmitted to any one parity bit storage unit 212 in the memory cell area 210 having the plurality of cell arrays stacked therein. In this embodiment, it is described that the parity bit storage unit 212 is positioned in the memory cell area 210. However, the present invention is not limited thereto, and the parity bit storage unit may be included in the ECC circuit 230. Here, it is described that the parity bit generation unit 231 according to the embodiment detects an error of the data signal according to the hamming code method. However, the present invention is not limited thereto, but an error may be detected according to a cyclic redundancy check (CRC) method. Here, the time required for calculating the parity bits using the write data signal WD may be compensated by a delay unit configured to delay the received write data signal WD.

The error detection unit 232 is configured to receive bits of the data signal RD read from the memory cell area 210 and the parity bits stored in the parity bit storage unit 212, and compare the read data signal RD to the parity bits so as to detect whether an error occurred or not, during a data read operation. When an error is detected, the error detection unit 232 transmits the read data signal RD to the error correction unit 233, and when an error is not detected, the error detection unit 232 outputs the read data signal RD to the data line DQL.

The error correction unit 233 is configured to generate an error correction code when the error detection unit 232 detects an error of the read data signal RD during the data read operation, and correct the error of the read data signal RD using the generated error correction code. The data signal Dout corrected in such a manner is transmitted to the data line DQL and outputted to the memory controller 100.

As described above, it can be seen that the ECC circuit 230 of the semiconductor memory apparatus 200 according to the embodiment operates in a slightly different manner between the data write operation and the data read operation. First, a control method for the data write operation of the semiconductor memory apparatus according to the embodiment will be described in more detail.

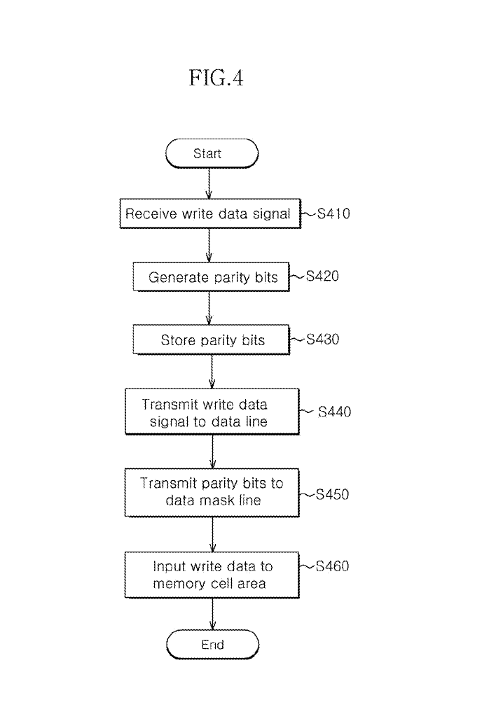

FIG. 4 is a flow chart showing the control method during the data write operation of the semiconductor memory apparatus according to the embodiment.

Referring to FIG. 4, the semiconductor memory apparatus 200 according to the embodiment receives a write data signal WD from the memory controller 100 at step S410, and generates parity bits using the received write data signal WD at step S420. The generation process may be performed as follows.

For example, when it is assumed that the bit number of the received write data signal WD is four, the number of parity bits generated by using the write data signal WD may be set to three. Table 1 shows a hamming code generated by using the write data signal WD.

TABLE 1

| | Bit number of write data | | | | | | |
|---|---|---|---|---|---|---|---|
| | 7 | 6 | 5 | 4 | 3 | 2 | 1 |
| Hamming code | WD7 | WD6 | WD5 | P4 | WD3 | P2 | P1 |

Here, when the write data signal is a decimal number 9, the decimal number 9 has a value of 1001 as a binary number. Therefore, the humming code may be represented as Table 2 below.

TABLE 2

| | Bit number of write data | | | | | | |
|---|---|---|---|---|---|---|---|
| | 7 | 6 | 5 | 4 | 3 | 2 | 1 |
| Hamming code | 1 | 0 | 0 | P4 | 1 | P2 | P1 |

Here, the bit value of the write data, i.e., 1001 is used to calculate the parity bits. Since the parity bits may be calculated by well-known technology, the detailed descriptions thereof are omitted herein.

The parity bits generated through the above-described process are stored in the parity bit storage unit 212 at step S430, the write data are transmitted through the data line DQL at step S440, and the generated parity bits are transmitted through the data mask line DML at step S450.

The write data transmitted through the data line DQL are inputted to the memory cell area at step S460.

As described above, the semiconductor memory apparatus 200 according to the embodiment generates the parity bits using the write data signal WD inputted from the memory controller 100 through the ECC circuit 230 of the control logic area 220, and transmits the generated parity bits to the data mask line DML, which makes it possible to improve the reliability of the semiconductor memory apparatus 200.

Meanwhile, a case in which a read command is inputted from the memory controller 100, that is, the read operation of the semiconductor memory apparatus 200 according to the embodiment will be described in more detail.

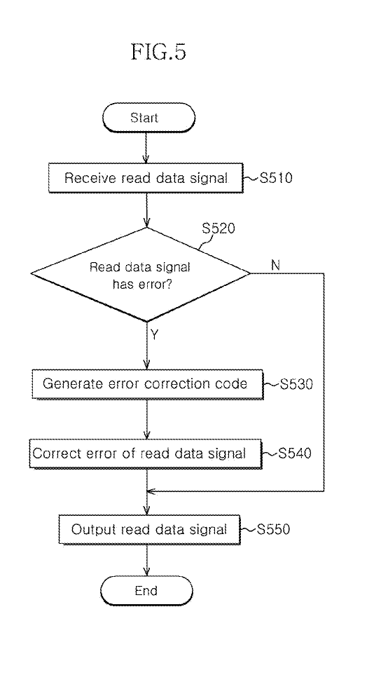

FIG. 5 is a flow chart showing a control method during the data read operation of the semiconductor memory apparatus according to the embodiment.

Referring to FIG. 5, the semiconductor memory apparatus 200 according to the embodiment receives a read data signal RD from the memory cell area 210 at step S510, and compares bits of the inputted read data signal RD to the parity bits stored in the parity bit storage unit 210 so as to determine whether the read data signal RD has an error or not at step S520.

As the determination result, when an error is not detected, the semiconductor memory apparatus 200 outputs the read data signal RD to the memory controller 100 through the data line DQL at step S550.

Meanwhile, when an error is detected, the semiconductor memory apparatus 200 generates an error correction code at step S530. Since the error correction code may be generated by technology known to those skilled in the art, the detailed descriptions thereof are omitted herein.

The semiconductor memory apparatus 200 corrects the error of the read data signal RD using the generated error correction code at step S540, and outputs the corrected read data signal RD to the memory controller 100 at step S550.

As described above, in the semiconductor memory apparatus 200 and the semiconductor system 1000 having the same according to the embodiment, the ECC circuit 230 configured to determine whether the write data signal WD or the read data signal RD has an error or not is included in the semiconductor memory apparatus 200. Therefore, it is possible to reduce the overhead of the memory controller 100 and the power required by the memory controller 100.

Furthermore, the ECC circuit 230 is provided in an extra space of the control logic area 220 for controlling the memory cell area 210 having the plurality of memory cell arrays integrated therein in the semiconductor memory apparatus 200 including the memory cell area 210 having the plurality of memory cell arrays stacked therein. Therefore, the area of the semiconductor memory apparatus 200 may be efficiently utilized.

Furthermore, the memory controller 100 receives only the data signal DQ through the data line DQL, and internally generates the parity bits. Therefore, since a protocol agreement between the memory controller 100 and the semiconductor memory apparatus 200 is not necessary, the cost may be reduced.

While certain embodiments have been described above, it will be understood to those skilled in the art that the embodiments described are by way of example only. Accordingly, the semiconductor apparatus and the semiconductor system described herein should not be limited based on the described embodiments. Rather, the semiconductor apparatus and the semiconductor system described herein should only be limited in light of the claims that follow when taken in conjunction with the above description and accompanying drawings.

What is claimed is:

1. A semiconductor memory apparatus comprising:
a memory cell area comprising a plurality of memory cell arrays stacked therein, each memory cell array having a plurality of memory cells integrated and formed therein to store data and a plurality of through-lines formed therein to transmit signals; and
a control logic area configured to generate parity bits using a data signal inputted to the memory cell area and transmit the generated parity bits and the data signal to different through-lines.

2. The semiconductor memory apparatus according to claim 1, wherein the control logic area comprises an error correcting code (ECC) circuit configured to generate the parity bits using the data signal inputted to the memory cell area and determine whether the data signal has an error or not, using the generated parity bits.

3. The semiconductor memory apparatus according to claim 2, wherein the ECC circuit transmits the data signal inputted to the memory cell area to a data line for transmitting the data signal, and transmits the parity bits generated by using the data signal to a data mask line for transmitting a data mask signal.

4. The semiconductor memory apparatus according to claim 2, wherein the ECC circuit comprises:
a parity bit generation unit configured to generate the parity bits using the data signal inputted to the memory cell area;
an error detection unit configured to compare the parity bits generated by the parity bit generation unit to a data signal outputted from the memory cell area and detect an error; and
an error correction unit configured to correct an error of the data signal outputted from the error detection unit, when data are outputted the memory cell area.

5. The semiconductor memory apparatus according to claim 4, wherein, when the data are outputted from the memory cell area, the error detection unit determines whether the outputted data signal has an error or not, transmits the data signal to the error correction unit when determining that the data signal has an error, and transmits the data signal to the data line for transmitting the data signal when determining that the data signal has no error.

6. The semiconductor memory apparatus according to claim 4, wherein the parity bit generation unit generates the parity bits according to a hamming code or cyclic redundancy check (CRC) method.

7. The semiconductor memory apparatus according to claim 1, wherein each of the memory cell arrays of the memory cell area comprises:
a normal cell array having normal cells integrated therein, the normal cells configured to receive and store the data signal; and
a parity bit storage unit configured to store the parity bits generated by using the data signal.

8. A semiconductor system comprising:
a memory controller configured to receive a command signal, an address signal, a data mask signal, and a data signal from outside and control data to be written or read; and
a semiconductor memory apparatus configured to receive write data from the memory controller, generate parity bits using the write data, transmit the write data and the parity bits to different through-lines, determine whether read data outputted to the memory controller have an error or not, and transmit the read data.

9. The semiconductor system according to claim 8, wherein the semiconductor memory apparatus comprises:
a memory cell area comprises a plurality of memory cell arrays stacked therein, each memory cell array having a plurality of memory cells integrated and formed therein to store the write data inputted from the memory controller and a plurality of through-lines formed therein to transmit signals; and
a control logic area configured to generate parity bits using the write data inputted from the memory controller, transmit the write data and the parity bits to different through-lines, determine whether read data outputted from the memory cell area have an error or not, using the generated parity bits, and transmit the read data.

10. The semiconductor system according to claim 9, wherein the control logic area comprises an ECC circuit configured to generate the parity bits using the write data and determine whether the read data have an error or not, using the generated parity bits.

11. The semiconductor system according to claim 10, wherein the ECC circuit transmits the write data to a data line for transmitting a data signal, and transmits the generated parity bits to a data mask line for transmitting a data mask signal.

12. The semiconductor system according to claim 10, is wherein the ECC circuit comprises:
a parity bit generation unit configured to generate the parity bits using the write data;
an error detection unit configured to detect an error of the read data using the parity bits generated by the parity bit generation unit and transmit the read data according to the detection result; and
an error correction unit configured to correct the error of the data signal outputted from the error detection unit, when read data are outputted from the memory cell area.

13. The semiconductor system according to claim 12, wherein the parity bit generation unit stores the parity bits generated by using the write data in the memory cell area.

14. The semiconductor system according to claim 12, wherein the error detection unit compares the read data to the parity bits stored in the memory cell area, determines whether the read data have an error or not, transmits the read data to the error correction unit when determining that the read data have an error, and transmits the read data to the data line for transmitting the read data when determining that the read data have no error.

15. The semiconductor system according to claim 12, wherein the parity bit generation unit generates the parity bits according to a hamming code or CRC method.
